(19) United States
(12) Patent Application Publication
(10) Pub. No.: US 2011/0084408 A1
(43) Pub. Date: Apr. 14, 2011

(54) THERMOSETTING DIE-BONDING FILM

(76) Inventors: Yuichiro Shishido, Osaka (JP); Naohide Takamoto, Osaka (JP)

(21) Appl. No.: 12/903,661

(22) Filed: Oct. 13, 2010

(30) Foreign Application Priority Data
Oct. 14, 2009 (JP) 2009-237601

(51) Int. Cl. H01L 23/14; C08L 63/00; B32B 27/38

(52) U.S. Cl. 257/783; 525/396; 428/413; 257/E23.04

(57) ABSTRACT

An object of the present invention is to provide a thermosetting die-bonding film that is capable of preventing warping of an adherend by suppressing curing contraction of the film after die bonding, and a dicing die-bonding film. The present invention relates to a thermosetting die-bonding film for adhering and fixing a semiconductor element onto an adherend, comprising at least an epoxy resin and a phenol resin as a thermosetting component, wherein the ratio of the number of moles of epoxy groups to the number of moles of phenolic hydroxyl groups in the thermosetting component is in a range of 1.5 to 6.

### FIELD OF THE INVENTION

The present invention relates to a thermosetting die-bonding film that is used when fixing a semiconductor element such as a semiconductor chip onto an adherend such as a substrate and a lead frame. The present invention further relates to a dicing die-bonding film in which the thermosetting die-bonding film and a dicing film are laminated.

### BACKGROUND OF THE INVENTION

A dicing die-bonding film that adheres and holds a semiconductor wafer in a dicing step and also provides an adhesive layer for fixing a chip that is necessary in a mounting step has been conventionally used in a manufacturing process of a semiconductor device (see Japanese Patent Application Laid-Open No. 60-57342). This dicing die-bonding film is configured by laminating the pressure-sensitive adhesive layer and the adhesive layer one by one on a support base. That is, the semiconductor wafer is diced while being held by the adhesive layer, the support base is stretched, and a semiconductor chip is picked up together with the die-bonding film. Furthermore, the semiconductor chip is die-bonded onto a die pad of the lead frame with the die-bonding film interposed therebetween.

However, since semiconductor wafers are becoming larger and thinner, semiconductor chips are also becoming thinner. When such semiconductor chips are fixed onto an adherend such as a substrate with the die-bonding film interposed therebetween and thermally cured (die bonding), curing contraction occurs due to the thermal curing of the die-bonding film. As a result, there is a problem that the adherend warps.

### SUMMARY OF THE INVENTION

The present invention has been made in view of the above-described problem, and an object thereof is to provide a thermosetting die-bonding film that is capable of preventing warping of an adherend by suppressing curing contraction of the film after die bonding, and a dicing die-bonding film.

The present inventors investigated a thermosetting die-bonding film and a dicing die-bonding film to solve the conventional problem. As a result, they found that curing contraction after thermal curing can be reduced by controlling the ratio of the number of moles of epoxy groups to the number of moles of phenolic hydroxyl groups in a thermosetting component, and completed the present invention.

That is, the present invention relates to a thermosetting die-bonding film for adhering and fixing a semiconductor element onto an adherend, comprising at least an epoxy resin and a phenol resin as a thermosetting component, wherein the ratio of the number of moles of epoxy groups to the number of moles of phenolic hydroxyl groups in the thermosetting component is in a range of 1.5 to 6.

When a semiconductor element is die-bonded onto an adherend using a thermosetting die-bonding film, the thermosetting die-bonding film is preferably thermally cured sufficiently in view of secure adhesion and fixing of the semiconductor element and the adherend. When an epoxy resin is used as the thermosetting component that constitutes the thermosetting die-bonding film and a phenol resin is used as a curing agent to the epoxy resin, the equivalent ratio of the epoxy groups contained in the epoxy resin and the equivalent ratio of the phenolic hydroxyl groups contained in the phenol resin are preferably the same. When the equivalent ratios are the same, the thermal curing reaction of the epoxy resin proceeds sufficiently, and a three dimensional crosslinking structure can be sufficiently formed. However, when the thermal curing reaction of the epoxy resin proceeds excessively, there is a case that the thermosetting die-bonding film itself cures and contracts.

In the present invention, the ratio of the number of moles of epoxy groups in the thermosetting component to the number of moles of phenolic hydroxyl groups in the thermosetting component is set in a range of 1.5 to 6 as in the above-described configuration, so that the number of moles of epoxy groups to the number of moles of phenolic hydroxyl groups is made higher than that of a conventional thermosetting die-bonding film. Accordingly, the tensile modulus of the thermosetting die-bonding film itself is reduced, and a reduction in the curing contraction is made possible. As a result, when a thermosetting die-bonding film having the above-described configuration is applied to the production of a semiconductor device, warping of an adherend can be suppressed during die bonding, and the throughput can be improved.

In the thermosetting die-bonding film, it is preferable that a thermosetting catalyst is compounded in an amount of 0.07 to 3.5 parts by weight to 100 parts by weight of an organic component. In the present invention, since the ratio of epoxy groups to phenolic hydroxyl groups is high, unreacted epoxy groups remain in the film even after the thermal curing. However, the thermosetting die-bonding film is preferably thermally cured sufficiently when the semiconductor element that is die-bonded onto the adherend is sealed with a sealing resin and a post curing step is further performed, for example. In the present invention, curing contraction can be reduced by compounding a thermosetting catalyst into the film as in the above-described configuration, thereby thermally curing the film to a level that the curing contraction does not occur when die-bonding the semiconductor element onto the adherend and polymerizing unreacted epoxy groups in the post curing step. As a result, a semiconductor device can be manufactured in which a semiconductor element is securely adhered and fixed onto the adherend and the semiconductor element would not be peeled from the adherend.

The unreacted epoxy groups can be eliminated and thermal curing of the thermosetting die-bonding film can be made to proceed sufficiently after the post curing step by setting the compounding amount of the thermosetting catalyst to 0.07 parts by weight or more with respect to 100 parts by weight of an organic component. On the other hand, by setting the compounding amount to 3.5 parts by weight or less, the thermal curing reaction of the thermosetting die-bonding film can be prevented from proceeding excessively in the post curing step, and the semiconductor element can be prevented from being peeled from the adherend and generation of voids can be prevented.

In the thermosetting die-bonding film, it is preferable that the glass transition temperature after thermal curing at 140° C. for 2 hours is 80° C. or less. By setting the glass transition temperature of the thermosetting die-bonding film to 80° C. or less, curing contraction of the film after thermal curing can be reduced further.

In the thermosetting die-bonding film, it is preferable that the melt viscosity at 120° C. before thermal curing is in a range of 50 to 1000 Pa·s. By setting the melt viscosity of the thermosetting die-bonding film before thermal curing to 50 Pa·s or more, good adhesion to the adherend can be achieved. As a result, generation of voids at the adhesion surface to the adherend can be decreased. By setting the melt viscosity to 1000 Pa·s or less, leaching of the adhesive component or the like from the thermosetting die-bonding film can be suppressed. As a result, contamination of the adherend and the semiconductor element that is to be adhered and fixed to the adherend can be prevented.

In the thermosetting die-bonding film, the storage modulus at 260° C. after complete thermal curing is preferably 1 MPa or more. Thereby, it is possible to manufacture a semiconductor device having high reliability even in a humidity resistance solder reflow test and therefore having a good humidity resistance reflow property.

Furthermore, in order to solve the above-mentioned problems, the present invention relates to a dicing die-bonding film having a structure in which the thermosetting die-bonding film is laminated on a dicing film.

Moreover, in order to solve the above-mentioned problems, the present invention relates to a semiconductor device manufactured by using the above-mentioned dicing die-bonding film.

The present invention has an effect described below with the above-explained means.

That is, according to the present invention, the thermosetting die-bonding film comprises at least an epoxy resin and a phenol resin as a thermosetting component, the ratio of the number of moles of epoxy groups in the thermosetting component to the number of moles of phenolic hydroxyl groups in the thermosetting component is set in a range of 1.5 to 6, and unreacted epoxy groups remain even after thermal curing, and therefore, the tensile modulus of the thermosetting die-bonding film itself is reduced, and a reduction in the curing contraction is made possible. As a result, when a thermosetting die-bonding film having the above-described configuration is applied to the production of a semiconductor device, warping of an adherend can be suppressed during die bonding, and the throughput can be improved.

### BRIEF DESCRIPTION OF THE DRAWINGS

FIG. 1 is a schematic sectional view showing a dicing die-bonding film of one embodiment of the present invention;

FIG. 2 is a schematic sectional view showing a dicing die-bonding film of another embodiment of the present invention;

FIG. 3 is a schematic sectional view showing an example of mounting a semiconductor chip with the die-bonding film of one embodiment of the present invention;

FIG. 4 is a schematic sectional view showing an example of three-dimensionally mounting a semiconductor chip with the die-bonding film; and

FIG. 5 is a schematic sectional view showing an example of three-dimensionally mounting two semiconductor chips with a spacer using the die-bonding film.

FIG. 6 is an explanatory drawing to explain a method of measuring the amount of warping in a semiconductor chip that is die-bonded onto a resin substrate with a solder resist through a thermosetting die-bonding film.

### DESCRIPTION OF THE EMBODIMENTS

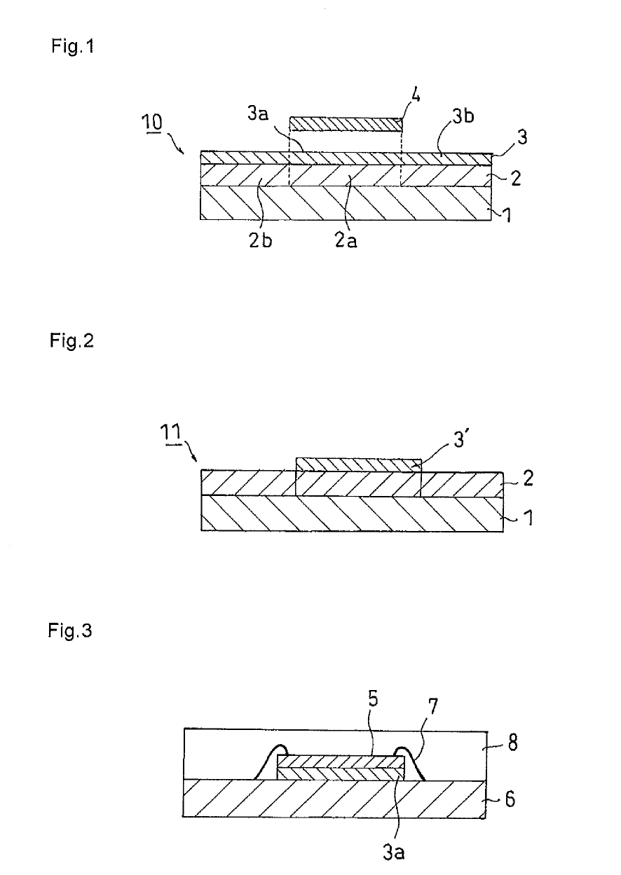

The thermosetting die-bonding film of the present embodiment (referred to as “a die-bonding film” below) is explained below using an embodiment of a dicing die-bonding film in which the thermosetting die-bonding film is laminated on a dicing film that is formed by laminating a pressure-sensitive adhesive layer 2 onto a base 1 as shown in FIG. 1 as an example.

The constituent material of the die-bonding film 3 is not especially limited as long as at least an epoxy resin and a phenol resin are used as thermosetting components.

The epoxy resin may be any epoxy resin that is ordinarily used as an adhesive composition. Examples thereof include bifunctional or polyfunctional epoxy resins such as bisphenol A type, bisphenol F type, bisphenol S type, brominated bisphenol A type, hydrogenated bisphenol A type, bisphenol AF type, biphenyl type, naphthalene type, fluorene type, phenol Novolak type, orthocresol Novolak type, tris-hydroxyphenylmethane type, and tetraphenylolethane type epoxy resins; hydantoin type epoxy resins; tris-glycicylisocyanurate type epoxy resins; and glycidylamine type epoxy resins. These may be used alone or in combination of two or more thereof. Among these epoxy resins, particularly preferable are Novolak type epoxy resin, biphenyl type epoxy resin, tris-hydroxyphenylmethane type epoxy resin, and tetraphenylolethane type epoxy resin, since these epoxy resins are rich in reactivity with phenol resin as an agent for curing the epoxy resin and are superior in heat resistance and so on. The epoxy resin has few ionic impurities, etc. that corrode the semiconductor element.

The phenol resin acts as a curing agent of the epoxy resin, and examples include novolak phenol resins such as a phenol novolak resin, a phenol aralkyl resin, a cresol novolak resin, a tert-butylphenol novolak resin, and a nonylphenol novolak resin, resol phenol resins, and polyoxystryrene such as polyparaoxystyrene. These can be used alone or two types or more can be used in combination. Among these phenol resins, a biphenyl phenol novolak resin and a phenol aralkyl resin are preferable because they can improve connection reliability of the semiconductor device.

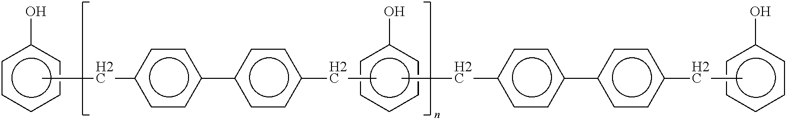

(In the formula, n is a natural number of 0 to 10.)

The value of n is preferably a natural number of 0 to 10, and more preferably a natural number of 0 to 5. By setting n in this range, fluidity of the die-bonding film 3 can be secured.

The epoxy resin and the phenol resin are compounded so that the ratio of the number of moles of epoxy groups in the thermosetting component to the number of moles of phenolic hydroxyl groups in the thermosetting component is in a range of 1.5 to 6. The ratio is preferably 1.5 to 4, and more preferably 2 to 3. By setting the ratio to 1.5 or more, the tensile modulus of the thermosetting die-bonding film itself can be reduced, and curing contraction can be reduced. By setting the ratio to 6 or less, the thermal curing reaction of the epoxy resin can be prevented from proceeding insufficiently.

The die-bonding film 3 according to the present embodiment may contain other thermosetting components as long as it is formed from an epoxy resin and a phenol resin as the thermosetting component. Examples of such other thermosetting components include an amino resin, an unsaturated polyester resin, a polyurethane resin, a silicone resin, and a thermosetting polyimide resin. Preferred are thermosetting components from which the solvent is removed, and which are made into a sheet and brought into a B stage. These resins can be used alone or two kinds or more can be used together. The compounding ratio of other thermosetting components is preferably in a range of 0.1 to 10 parts by weight and more preferably in a range of 0.4 to 5 parts by weight to 100 parts by weight of the thermosetting component.

A thermoplastic component is preferably used in the constituent materials of the die-bonding film 3. The thermoplastic component is not especially limited, but an acrylic resin is preferable, for example. The acrylic resin may be, for example, a polymer comprising, as a component or components, one or more esters of acrylic acid or methacrylic acid having a linear or branched alkyl group having 30 or less carbon atoms, in particular, 4 to 18 carbon atoms. Examples of the alkyl group include methyl, ethyl, propyl, isopropyl, n-butyl, t-butyl, isobutyl, amyl, isoamyl, hexyl, heptyl, cyclohexyl, 2-ethylhexyl, octyl, isooctyl, nonyl, isononyl, decyl, isodecyl, undecyl, lauryl, tridecyl, tetradecyl, stearyl, octadecyl, and dodecyl groups.

A different monomer which constitutes the above-mentioned polymer is not limited to any especial kind, and examples thereof include carboxyl-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxymethylcyclohexyl)methylacrylate; monomers which contain a sulfonic acid group, such as styrenesulfonic acid, allylsulfonic acid, 2-(meth)acrylamide-2-methylpropanesulfonic acid, (meth)acrylamidepropane sulfonic acid, sulfopropyl (meth)acrylate, and (meth) acryloyloxynaphthalenesulfonic acid; and monomers which contain a phosphoric acid group, such as 2-hydroxyethylacryloyl phosphate. These can be used alone or two kinds or more can be used together.

When an acrylic resin is used as the thermoplastic component, as for the compounding ratio of the epoxy resin and the phenol resin, the mixed amount of the epoxy resin and the phenol resin is preferably in a range of 10 to 700 parts by weight, and more preferably in a range of 20 to 600 parts by weight to 100 parts by weight of the acrylic resin. Because the epoxy resin, the phenol resin, and the acrylic resin have little ionic impurities and high heat resistance, reliability of a semiconductor element can be secured.

A thermosetting catalyst may be used as a constituent material of the die-bonding film 3 in the present embodiment. The compounding ratio of the thermosetting catalyst is preferably in a range of 0.01 to 3.5 parts by weight, more preferably in a range of 0.01 to 1 part by weight, and especially preferably in a range of 0.01 to 0.5 parts by weight to 100 parts by weight of an organic component. By setting the compounding ratio to 0.01 parts by weight or more, the epoxy groups that are unreacted at the time of die bonding can be polymerized by the post curing step, for example, and the unreacted epoxy groups can be reduced or eliminated. As a result, a semiconductor device can be manufactured in which a semiconductor element is securely adhered and fixed onto an adherend (described later in detail) and would not be peeled from the adherend. On the other hand, by setting the compounding ratio to 3.5 parts by weight or less, generation of curing hindrance can be prevented.

The thermosetting catalyst is not especially limited, and examples thereof include imidazole compounds, triphenylphosphine compounds, amine compounds, triphenylborane compounds, and trihalogenborane compounds. These can be used alone or two kinds or more can be used together.

Examples of the imidazole compounds include 2-methylimidazole (trade name: 2MZ), 2-undecylimidazole (trade name: C11Z), 2-heptadecylimidazole (trade name: C17Z), 1,2-dimethylimidazole (trade name: 1.2DMZ), 2-ethyl-4-methylimidazole (trade name: 2E4MZ), 2-pehnylimidazole (trade name: 2PZ), 2-phenyl-4-methylimidazole (trade name: 2P4MZ), 1-benzyl-2-methylimidazole (trade name: 1B2MZ), 1-benzyl-2-phenylimidazole (trade name: 1B2PZ), 1-cyanoethyl-2-methylimidazole (trade name: 2MZ-CN), 1-cyanoethyl-2-undecylimidazole (trade name: C11Z-CN), 1-cyanoethyl-2-phenylimidazoliumtrimellitate (trade name: 2PZCNS-PW), 2,4-diamino-6-[2′-methylimidazolyl-(1′)]-ethyl-s-triazine (trade name: 2MZ-A), 2,4-diamino-6-[2′-undecylimidazolyl-(1′)]-ethyl-s-triazine (trade name: C11Z-A), 2,4-diamino-6-[2′-ethyl-4′-methylimidazolyl-(1′)]-ethyl-s-t riazine (trade name: 2E4MZ-A), 2,4-diamino-6-[2′-methylimidazolyl-(1′)]-ethyl-s-triazine isocyanuric acid adduct (trade name: 2MA-OK), 2-phenyl-4,5-dihydroxymethylimidazole (trade name: 2PHZ-PW), and 2-phenyl-4-methyl-5-hydroxymethylimidazole (trade name: 2P4 MHZ-PW) (all of the compounds are manufactured by Shikoku Chemicals Corporation).

The triphenylphosphine compounds are not particularly limited and include, for example, triorganophosphines such as triphenylphosphine, tributylphosphine, tri(p-methylphenyl)phosphine, tri(nonylphenyl)phosphine and diphenyltolylphosphine, tetraphenylphosphonium bromide (TPP-PB), methyltriphenylphosphonium (trade name; TPP-MB), methyltriphenylphosphonium chloride (trade name; TPP-MC), methoxymethyltriphenylphosphonium (trade name; TPP-MOC) and benzyltriphenylphosphonium chloride (trade name; TPP-ZC) (all of which are manufactured by HOKKO CHEMICAL INDUSTRY CO. LTD.). Preferably, the triphenylphosphine compounds also substantially exhibit insolubility in the epoxy resin. When the thermosetting catalyst is insoluble in the epoxy resin, it is possible to suppress thermal setting from excessively proceeding. The thermosetting catalyst which has a triphenylphosphine structure and also substantially exhibits insolubility in the epoxy resin includes, for example, methyltriphenylphosphonium (trade name; TPP-MB). The “insolubility” means that the thermosetting catalysts composed of the triphenylphosphine compounds are insoluble in a solvent composed of an epoxy resin, and more specifically means that 10% by weight or more of the thermosetting catalyst does not dissolve at the temperature within a range from 10 to 40° C.

The triphenylborane compounds are not particularly limited and further includes, for example, tri(p-methylphenyl)phosphine. The triphenylborane compounds include those having also a triphenylphosphine structure. The compounds having a triphenylphosphine structure and a triphenylborane structure are not particularly limited and include tetraphenylphosphonium tetraphenylborate (trade name; TPP-K), tetraphenylphosphonium tetra-p-triborate (trade name; TPP-MK) benzyltriphenylphosphonium tetraphenylborate (trade name; TPP-ZK) and triphenylphosphine triphenylborane (trade name; TPP-S) (all of which are manufactured by HOKKO CHEMICAL INDUSTRY CO., LTD.).

The amine compounds are not particularly limited and includes, for example, monoethanolamine trifluoroborate (manufactured by Stella Chemifa Corporation) and dicyandiamide (manufactured by NACALAI TESQUE, INC.).

The trihalogenborane compounds are not especially limited, and, for example, trichloroborane is exemplified.

In order to crosslink the die-bonding film 3 of the present invention to some extent in advance, it is preferable to add, as a crosslinking agent, a polyfunctional compound which reacts with functional groups of molecular chain terminals of the above-mentioned polymer to the materials used when the sheet 12 is produced. In this way, the adhesive property of the sheet at high temperatures is improved so as to improve the heat resistance.

The crosslinking agent may be one known in the prior art. Particularly preferable are polyisocyanate compounds, such as tolylene diisocyanate, diphenylmethane diisocyanate, p-phenylene diisocyanate, 1,5-naphthalene diisocyanate, and adducts of polyhydric alcohol and diisocyanate. The amount of the crosslinking agent to be added is preferably set to 0.05 to 7 parts by weight for 100 parts by weight of the above-mentioned polymer. If the amount of the crosslinking agent to be added is more than 7 parts by weight, the adhesive force is unfavorably lowered. On the other hand, if the adding amount is less than 0.05 part by weight, the cohesive force is unfavorably insufficient. A different polyfunctional compound, such as an epoxy resin, together with the polyisocyanate compound may be incorporated if necessary.

An inorganic filler may be appropriately incorporated into the die-bonding film 3 of the present invention in accordance with the use purpose thereof. The incorporation of the inorganic filler makes it possible to confer electric conductance to the sheet, improve the thermal conductivity thereof, and adjust the elasticity. Examples of the inorganic fillers include various inorganic powders made of the following: a ceramic such as silica, clay, plaster, calcium carbonate, barium sulfate, aluminum oxide, beryllium oxide, silicon carbide or silicon nitride; a metal such as aluminum, copper, silver, gold, nickel, chromium, lead, tin, zinc, palladium or solder, or an alloy thereof; and carbon. These may be used alone or in combination of two or more thereof. Among these, silica, in particular fused silica is preferably used. The average particle size of the inorganic filler is preferably from 0.1 to 80 μm. The compounding amount of the inorganic filler is preferably set within a range from 0 to 80 parts by weight, and particularly preferably from 0 to 70 parts by weight, based on 100 parts by weight of the organic resin component.

If necessary, other additives besides the inorganic filler may be incorporated into the die-bonding film 3 of the present invention. Examples thereof include a flame retardant, a silane coupling agent, and an ion trapping agent. Examples of the flame retardant include antimony trioxide, antimony pentaoxide, and brominated epoxy resin. These may be used alone or in combination of two or more thereof. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These may be used alone or in combination of two or more thereof. Examples of the ion trapping agent include hydrotalcite and bismuth hydroxide. These may be used alone or in combination of two or more thereof.

The die-bonding films 3 of the dicing die-bonding films 10, 11 are preferably protected by a separator (not shown). The separator has a function as a protecting material that protects the die-bonding films 3 until they are practically used. Further, the separator can be used as a supporting base material when transferring the die-bonding films 3 to the pressure-sensitive adhesive layer 2. The separator is peeled when pasting a workpiece onto the die-bonding films 3 of the dicing die-bonding film. Polyethylenetelephthalate (PET), polyethylene, polypropylene, a plastic film, a paper, etc. whose surface is coated with a peeling agent such as a fluorine based peeling agent and a long chain alkylacrylate based peeling agent can be also used as the separator.

The glass transition temperature of the die-bonding film 3 after thermal curing is preferably 80° C. or less, more preferably 20 to 70° C., and especially preferably 20 to 50° C. By setting the glass transition temperature to 80° C. or less, the curing contraction of the die-bonding film 3 can be reduced further. The “thermal curing” means that the film is thermally cured by a heat treatment at 140° C. for 2 hours. The glass transition temperature can be measured and calculated by the following measurement method. That is, the die-bonding film 3 is thermally cured by a heat treatment at 140° C. for 2 hours. Then, the film 3 is cut into a rectangular shape of 200 μm thick, 400 mm long (measured length), and 10 mm wide with a cutting knife, and the storage modulus and the loss modulus at −50 to 300° C. are measured using a solid viscoelasticity measurement apparatus (RSA-III manufactured by Rheometric Scientific, Inc.). The conditions of the measurement are as follow: a frequency of 1 Hz and a temperature rising speed of 10° C./min. The glass transition temperature can be obtained by calculating the value of tan δ (G″ (loss modulus)/G′ (storage modulus)).

The melt viscosity of the die-bonding film 3 at 120° C. before thermal curing is preferably 50 to 1000 Pa·s, more preferably 100 to 800 Pa·s, and especially preferably 200 to 600 Pa·s. By setting the melt viscosity to 50 Pa·s or more, good adhesion to the adherend such as a substrate can be achieved. As a result, generation of voids at the adhesion surface to the adherend can be decreased. On the other hand, by setting the melt viscosity to 1000 Pa·s or less, leaching of the adhesive component or the like from the thermosetting die-bonding film can be suppressed. As a result, contamination of the adherend and the semiconductor element that is to be adhered and fixed to the adherend can be prevented. The melt viscosity can be measured and calculated by the following measurement method. That is, the melt viscosity can be measured by a parallel plate method using a rheometer (manufactured by HAAKE, RS-1). That is, 0.1 g of a sample is prepared from the die-bonding film 3 and placed on a plate heated to 100° C., and the measurement is started. The average value of the values measured after 120 seconds from start of the measurement is defined as the melt viscosity. The gap between the plates is 0.1 mm.

The storage modulus of the die-bonding film 3 at 260° C. after complete thermal curing is preferably 1 MPa or more, more preferably 5 to 100 MPa, and especially preferably 10 to 100 MPa. With the storage modulus in these ranges, the semiconductor element can be prevented from inclining in a sealing step, and it is possible to prevent generation of peeling between the die-bonding film and the adherend in a solder reflow step. The complete thermal curing of the die-bonding film 3 referred to here means a state after a heat treatment is performed at 140° C. for 2 hours and then a heat treatment is further performed at 175° C. for 1 hour. The measurement of the storage modulus can be performed by using a solid viscoelasticity measurement apparatus (RSA-III manufactured by Rheometric Scientific, Inc.) for example. That is, a measurement sample having a size of 400 mm in length×10 mm in width×200 μm in thickness is set in a tool for film tensile measurement, the tensile storage modulus and the tensile loss modulus in a temperature range of −50 to 300° C. are measured under conditions of a frequency of 1 Hz and a temperature rising speed of 10° C./min, and the storage modulus (E′) at 260° C. is read out, thereby obtaining the storage modulus.

The thickness (the total thickness as a laminated body) of the die-bonding film 3 is not particularly limited. However, it is about 5 to 100 and preferably about 5 to 50

The die-bonding 3 film can be configured only as a single layer of the adhesive layer, for example. It may have a multi-layer structure of two layers or more by appropriately combining thermoplastic resins having different glass transition temperatures and thermosetting resins having different thermosetting temperatures. Since a cutting liquid is used in the dicing step of a semiconductor wafer, the die-bonding film 3 absorbs moisture, and there is a case that the water content becomes a normal state or more. When the die-bonding film is adhered to a substrate, etc. with such high water content, water vapor stays on the adhesion interface at the stage after curing, and there is a case that floating occurs. Therefore, the die-bonding film 3 have a structure in which a core material having high moisture permeability is sandwiched between the adhesive layer, which thus makes it possible to avoid such a problem by diffusing the water vapor through the film at the stage after curing. From such a viewpoint, the die-bonding film may have a multi-layer structure in which the adhesive layer is formed on one side or both sides of the core material.

Examples of the core material include a film such as a polyimide film, a polyester film, a polyethylene terephthalate film, a polyethylene naphthalate, and a polycarbonate film, a resin substrate reinforced by a glass fiber or a plastic non-woven fiber, a mirror wafer, a silicon substrate, and a glass substrate.

The die-bonding film 3 is preferably protected by a separator (not shown in the drawings). The separator has a function as a protecting material of protecting the die-bonding film until it is put into a practical use. Further, the separator can be used as a support base when transferring the die-bonding film 3 to the dicing film. The separator is peeled off when pasting the workpiece onto the die-bonding film. Polyethylene terephthalate (PET), polyethylene, polypropylene, a plastic film whose surface is coated with a peeling agent such as a fluorine peeling agent and a long chain alkyl acrylate peeling agent, a paper, etc. can be used as the separator.

An example of the dicing film is a film in which the pressure-sensitive adhesive layer 2 is laminated on the base 1. The die-bonding film 3 is laminated on the pressure-sensitive adhesive layer 2. As shown in FIG. 2, the dicing film may have a configuration in which the die-bonding film 3′ is formed only on a semiconductor wafer pasting portion.

The base 1 becomes a strength base of the dicing die-bonding film 10, 11. Examples include polyolefins such as low-density polyethylene, straight-chain polyethylene, medium-density polyethylene, high-density polyethylene, super low-density polyethylene, random-copolymerized polyethylene, block-copolymerized polyethylene, homo-polyethylene, polybutene, and polymethylpentene, an ethylene-vinylacetate copolymer, an ionomer resin, an ethylene-(meth)acrylate copolymer, an ethylene-(meth)acrylic ester (random, alternating) copolymer, an ethylene-butene copolymer, an ethylene-hexene copolymer, polyurethane, polyester such as polyethylene terephthalate and polyethylene naphthalate, polycarbonate, polyimide, polyetheretherketone, polyetherimide, polyamide, wholly aromatic polyamide, polyphenylsulfide, aramid (paper), glass, glass cloth, a fluorine resin, polyvinyl chloride, polyvinylidene chloride, a cellulose resin, a silicone resin, metal (foil), and a paper. When the pressure-sensitive adhesive layer 2 is an ultraviolet ray curing type, a material that permits ultraviolet ray to pass through is preferable as the base 1.

An example of the material of the base 1 is a polymer such as a crosslinked body of the above-described resins. The above-described plastic film may be used in a non-stretched state, or a film may be used on which a mono-axial or a biaxial stretching treatment is performed depending on necessity. With a resin sheet in which a heat shrinking property is given by the stretching treatment, etc., recovery of the semiconductor chip can be easily attempted by reducing the adhesion area of the pressure-sensitive adhesive layer 2 with the die-bonding film 3 by heat-shrinking the base 1 after dicing.

The surface of the base 1 can be treated with a traditional surface treatment such as a chemical or a physical treatment such as a chromic acid treatment, an ozone exposure, a flame exposure, a high-voltage electric-shock exposure, and an ionized radiation treatment, and a coating treatment with a primer such as pressure-sensitive adhesive materials described later.

The same types or different types of the materials can be appropriately selected and used as the base 1, and several types can be blended and used depending on necessity. Further, an evaporation layer of a conductive material having a thickness of about 30 to 500 angstroms made of metals, alloys, or oxides of these, etc. can be provided on the base 1 to give antistatic property. The base 1 may be a single layer or a multi-layer of two types or more.

The thickness of the base 1 is not particularly limited and is appropriately determined. However, it is generally about 5 to 200 μm.

The base 1 may contain various additives such as a coloring agent, a filler, a plasticizer, an anti-aging agent, an antioxidant, a surfactant, and a flame retardant in a range that does not spoil the effects, etc. of the present invention.

The pressure-sensitive adhesive that is used to form the pressure-sensitive adhesive layer 2 is not especially limited as long as it can control pleelability of the die-bonding film 3. General pressure-sensitive adhesives such as an acrylic pressure-sensitive adhesive and a rubber pressure-sensitive adhesive can be used, for example. The pressure-sensitive adhesive is preferably an acrylic pressure-sensitive adhesive containing an acrylic polymer as a base polymer in view of clean washing of electronic components such as a semiconductor wafer and glass, which are easily damaged by contamination, with ultrapure water or an organic solvent such as alcohol.

Specific examples of the acrylic polymers include an acrylic polymer in which acrylate is used as a main monomer component. Examples of the acrylate include alkyl (meth)acrylate (for example, a straight chain or branched chain alkyl ester having 1 to 30 carbon atoms, and particularly 4 to 18 carbon atoms in the alkyl group such as methylester, ethylester, propylester, isopropylester, butylester, isobutylester, sec-butylester, t-butylester, pentylester, isopentylester, hexylester, heptylester, octylester, 2-ethylhexylester, isooctylester, nonylester, decylester, isodecylester, undecylester, dodecylester, tridecylester, tetradecylester, hexadecylester, octadecylester, and eicosylester) and cycloalkyl(meth)acrylate (for example, cyclopentylester, cyclohexylester, etc.). These monomers may be used alone or two or more types may be used in combination. The (meth) acrylic acid ester means an acrylic acid ester and/or a methacrylic acid ester, and has very the same meaning as (meth) in the present invention.

The acrylic polymer may optionally contain a unit corresponding to a different monomer component copolymerizable with the above-mentioned alkyl ester of (meth)acrylic acid or cycloalkyl ester thereof in order to improve the cohesive force, heat resistance or some other property of the polymer. Examples of such a monomer component include carboxyl-containing monomers such as acrylic acid, methacrylic acid, carboxyethyl (meth)acrylate, carboxypentyl(meth)acrylate, itaconic acid, maleic acid, fumaric acid, and crotonic acid; acid anhydride monomers such as maleic anhydride, and itaconic anhydride; hydroxyl-containing monomers such as 2-hydroxyethyl (meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxylmethylcyclohexyl)methyl(meth)acrylate; sulfonic acid group containing monomers such as styrenesulfonic acid, allylsulfonic acid, 2-(meth)acrylamide-2-methylpropanesulfonic acid, (meth) acrylamidepropanesulfonic acid, sulfopropyl (meth)acrylate, and (meth)acryloyloxynaphthalenesulfonic acid; phosphoric acid group containing monomers such as 2-hydroxyethylacryloyl phosphate; acrylamide; and acrylonitrile. These copolymerizable monomer components may be used alone or in combination of two or more thereof. The amount of the copolymerizable monomer (s) to be used is preferably 40% by weight or less of all the monomer components.

For crosslinking, the acrylic polymer can also contain multifunctional monomers if necessary as the copolymerizable monomer component. Such multifunctional monomers include hexane dioldi(meth)acrylate, (poly)ethyleneglycoldi(meth)acrylate, (poly)propylene glycol di(meth)acrylate, neopentyl glycol di(meth)acrylate, pentaerythritol di(meth)acrylate, trimethylol propane tri(meth)acrylate, pentaerythritol tri(meth)acrylate, dipentaerythritol hexa(meth)acrylate, epoxy(meth)acrylate, polyester (meth)acrylate, urethane (meth)) acrylate etc. These multifunctional monomers can also be used as a mixture of one or more thereof. From the viewpoint of adhesiveness etc., the use amount of the multifunctional monomer is preferably 30 wt % or less based on the whole monomer components.

Preparation of the Above Acryl Polymer can be Performed by applying an appropriate manner such as a solution polymerization manner, an emulsion polymerization manner, a bulk polymerization manner, and a suspension polymerization manner to a mixture of one or two or more kinds of component monomers for example. Since the pressure-sensitive adhesive layer preferably has a composition in which the content of low molecular weight materials is suppressed from the viewpoint of prevention of wafer contamination, and since those in which an acryl polymer having a weight average molecular weight of 300000 or more, particularly 400000 to 3000000 is as a main component are preferable from such viewpoint, the pressure-sensitive adhesive can be made to be an appropriate cross-linking type with an internal cross-linking manner, an external cross-linking manner, etc.

To increase the number-average molecular weight of the base polymer such as acrylic polymer etc., an external crosslinking agent can be suitably adopted in the pressure-sensitive adhesive. The external crosslinking method is specifically a reaction method that involves adding and reacting a crosslinking agent such as a polyisocyanate compound, epoxy compound, aziridine compound, melamine crosslinking agent, urea resin, anhydrous compound, polyamine, carboxyl group-containing polymer. When the external crosslinking agent is used, the amount of the crosslinking agent to be used is determined suitably depending on balance with the base polymer to be crosslinked and applications thereof as the pressure-sensitive adhesive. Generally, the crosslinking agent is preferably incorporated in an amount of about 5 parts by weight or less, and more preferably 0.1 to 5 parts by weight based on 100 parts by weight of the base polymer. The pressure-sensitive adhesive may be blended not only with the components described above but also with a wide variety of conventionally known additives such as a tackifier, and aging inhibitor, if necessary.

The pressure-sensitive adhesive layer 2 is constituted by containing an radiation curable pressure sensitive adhesive. The radiation curable pressure sensitive adhesive can easily decrease its adhesive strength by increasing the degree of crosslinking by irradiation with radiation such as ultraviolet ray. By irradiating only a part 2a of the pressure-sensitive adhesive layer 2 shown in FIG. 2, a difference of the adhesive strength to a part 2b can be also provided.

Further, by curing the radiation curable pressure-sensitive adhesive layer 2 with the die-bonding film 3′, the part 2a in which the adhesive strength is remarkably decreased can be formed easily. Because the die-bonding film 3′ is pasted to the part 2a in which the adhesive strength is decreased by curing, the interface of the part 2a and the die-bonding film 3′ has a characteristic of being easily peeled during pickup. On the other hand, the part not irradiated has sufficient adhesive strength, and forms the part 2b.

As described above, in the pressure-sensitive adhesive layer 2 of the dicing die-bonding film 10 shown in FIG. 1, the part 2b formed by a non-cured radiation curable pressure sensitive adhesive sticks to the die-bonding film 3, and the holding force when dicing can be secured. In such a way, the radiation curable pressure sensitive adhesive can support the die-bonding film 3 for fixing the semiconductor chip (semiconductor chip and the like) onto an adherend such as a substrate with good balance of adhesion and peeling. In the pressure-sensitive adhesive layer 2 of the dicing die-bonding film 11 shown in FIG. 2, a dicing ring can be fixed to the part 2b.

The radiation curable pressure sensitive adhesive that is used has a radiation curable functional group of a radical reactive carbon-carbon double bond, etc., and adherability. Examples of the radiation curable pressure sensitive adhesive are an added type radiation curable pressure sensitive adhesive in which a radiation curable monomer component or an oligomer component is compounded into an acryl pressure sensitive adhesive or a rubber pressure sensitive adhesive.

Examples of the radiation curable monomer component to be compounded include such as an urethane oligomer, urethane (meth)acrylate, trimethylolpropane tri(meth)acrylate, tetramethylolmethane tetra(meth)acrylate, pentaerythritol tri(meth)acrylate, pentaerythritol tetra(meth)acrylate, dipentaerythritol monohydroxypenta(meth)acrylate, dipentaerythritol hexa(meth)acrylate, and 1,4-butane dioldi(meth)acrylate. Further, the radiation curable oligomer component includes various types of oligomers such as an urethane based, a polyether based, a polyester based, a polycarbonate based, and a polybutadiene based oligomer, and its molecular weight is appropriately in a range of about 100 to 30,000. The compounding amount of the radiation curable monomer component and the oligomer component can be appropriately determined to an amount in which the adhesive strength of the pressure-sensitive adhesive layer can be decreased depending on the type of the pressure-sensitive adhesive layer. Generally, it is for example 5 to 500 parts by weight, and preferably about 40 to 150 parts by weight based on 100 parts by weight of the base polymer such as an acryl polymer constituting the pressure sensitive adhesive.

Further, besides the added type radiation curable pressure sensitive adhesive described above, the radiation curable pressure sensitive adhesive includes an internal radiation curable pressure sensitive adhesive using an acryl polymer having a radical reactive carbon-carbon double bond in the polymer side chain, in the main chain, or at the end of the main chain as the base polymer. The internal radiation curable pressure sensitive adhesives of an internally provided type are preferable because they do not have to contain the oligomer component, etc. that is a low molecular weight component, or most of them do not contain, they can form a pressure-sensitive adhesive layer having a stable layer structure without migrating the oligomer component, etc. in the pressure sensitive adhesive over time.

The above-mentioned base polymer, which has a carbon-carbon double bond, may be any polymer that has a carbon-carbon double bond and further has viscosity. As such a base polymer, a polymer having an acrylic polymer as a basic skeleton is preferable. Examples of the basic skeleton of the acrylic polymer include the acrylic polymers exemplified above.

The method for introducing a carbon-carbon double bond into any one of the above-mentioned acrylic polymers is not particularly limited, and may be selected from various methods. The introduction of the carbon-carbon double bond into a side chain of the polymer is easier in molecule design. The method is, for example, a method of copolymerizing a monomer having a functional group with an acrylic polymer, and then causing the resultant to condensation-react or addition-react with a compound having a functional group reactive with the above-mentioned functional group and a carbon-carbon double bond while keeping the radial ray curability of the carbon-carbon double bond.

Examples of the combination of these functional groups include a carboxylic acid group and an epoxy group; a carboxylic acid group and an aziridine group; and a hydroxyl group and an isocyanate group. Of these combinations, the combination of a hydroxyl group and an isocyanate group is preferable from the viewpoint of the easiness of reaction tracing. If the above-mentioned acrylic polymer, which has a carbon-carbon double bond, can be produced by the combination of these functional groups, each of the functional groups may be present on any one of the acrylic polymer and the above-mentioned compound. It is preferable for the above-mentioned preferable combination that the acrylic polymer has the hydroxyl group and the above-mentioned compound has the isocyanate group. Examples of the isocyanate compound in this case, which has a carbon-carbon double bond, include methacryloyl isocyanate, 2-methacryloyloxyethyl isocyanate, and m-isopropenyl-α,α-dimethylbenzyl isocyanate. The used acrylic polymer may be an acrylic polymer copolymerized with any one of the hydroxyl-containing monomers exemplified above, or an ether compound such as 2-hydroxyethyl vinyl ether, 4-hydroxybutyl vinyl ether or diethylene glycolmonovinyl ether.

The intrinsic type radial ray curable adhesive may be made only of the above-mentioned base polymer (in particular, the acrylic polymer), which has a carbon-carbon double bond. However, the above-mentioned radial ray curable monomer component or oligomer component may be incorporated into the base polymer to such an extent that properties of the adhesive are not deteriorated. The amount of the radial ray curable oligomer component or the like is usually 30 parts or less by weight, preferably from 0 to 10 parts by weight for 100 parts by weight of the base polymer.

In the case that the radial ray curable adhesive is cured with ultraviolet rays or the like, a photopolymerization initiator is preferably incorporated into the adhesive. Examples of the photopolymerization initiator include α-ketol compounds such as 4-(2-hydroxyethoxy)phenyl(2-hydroxy-2-propyl)ketone, α-hydroxy-α,α′-dimethylacetophenone, 2-methyl-2-hydroxypropiophenone, and 1-hydroxycyclohexyl phenyl ketone; acetophenone compounds such as methoxyacetophenone, 2,2-dimethoxy-2-phenylacetophenone, 2,2-diethoxyacetophenone, and 2-methyl-1-[4-(methylthio)-phenyl]-2-morpholinopropane-1; benzoin ether compounds such as benzoin ethyl ether, benzoin isopropyl ether, and anisoin methyl ether; ketal compounds such as benzyl dimethyl ketal; aromatic sulfonyl chloride compounds such as 2-naphthalenesulfonyl chloride; optically active oxime compounds such as 1-phenone-1,1-propanedione-2-(o-ethoxycarbonyl)oxime; benzophenone compounds such as benzophenone, benzoylbenzoic acid, and 3,3′-dimethyl-4-methoxybenzophenone; thioxanthone compound such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketones; acylphosphonoxides; and acylphosphonates. The amount of the photopolymerization initiator to be blended is, for example, from about 0.05 to 20 parts by weight for 100 parts by weight of the acrylic polymer or the like which constitutes the adhesive as a base polymer.

When the pressure-sensitive adhesive layer 2 is formed from a radiation curable pressure-sensitive adhesive, a portion of the pressure-sensitive adhesive layer 2 is preferably radiated so that the adhesive power of a portion 2a becomes smaller than the adhesive power of a portion 2b. For the dicing die-bonding film in FIG. 2, the adhesive power of the portion 2a is made to be smaller than the adhesive power of the portion 2b in view of the relationship with an SUS304 plate (#2000 polished) as the adherend.

An example of a method of forming the portion 2a onto the pressure-sensitive adhesive layer 2 is a method of forming the radiation curing-type pressure-sensitive adhesive layer 2 onto the base 1 and then curing by irradiating partially the portion 2a with radiation. The partial irradiation can be performed through a photo mask in which a pattern corresponding to a portion 3b, etc. other than the semiconductor wafer pasting portion 3a is formed. Another example includes a method of curing by irradiating with ultraviolet ray in spot manner. The formation of the radiation curing-type pressure-sensitive adhesive layer 2 can be performed by transferring the pressure-sensitive adhesive layer 2 provided on a separator onto the base 1. The partial irradiation can also be performed on the radiation curing-type pressure-sensitive adhesive layer 2 provided on a separator.

When the pressure-sensitive adhesive layer 2 is formed from a radiation curable pressure-sensitive adhesive, the portion 2a can be formed where the adhesive strength is decreased by using the base 1 of which the entire or apart of the portion other than the portion corresponding to the semiconductor wafer pasting portion 3a of at least one side of the base 1 is shielded, forming the radiation curing-type pressure-sensitive adhesive layer 2 onto the base 1, and then curing the portion corresponding to the semiconductor wafer pasting portion 3a by irradiation. A material that can be a photo mask on a support film can be manufactured by printing, vapor deposition, etc. as the shielding material. Accordingly, the dicing die-bonding film 10 of the present invention can be manufactured with good efficiency.

When an impediment to curing due to oxygen occurs during the irradiation, it is desirable to shut off oxygen (air) from the surface of the radiation curing-type pressure-sensitive adhesive layer 2. Examples of the method include a method of coating the surface of the pressure-sensitive adhesive layer 2 with a separator and a method of performing the irradiation with radiation such as the ultraviolet ray in a nitrogen gas atmosphere.

The thickness of the pressure-sensitive adhesive layer 2 is not particularly limited. However, it is preferably about 1 to 50 μm from the respects of managing the prevention of breaking of the chip cut face and fixing and holding the adhesive layer at the same time, etc. It is more preferably 2 to 30 μm, and further preferably 5 to 25 μm. The pressure-sensitive adhesive layer 2 may be made of a single layer or may be made of a plurality of layers that are laminated.

Various additives such as a coloring agent, a thickening agent, an extender, a filler, a tackifier, a plasticizer, an anti-aging agent, an antioxidant, a surfactant, and a crosslinking agent may be included in the pressure-sensitive adhesive layer 2 within the range that the effect of the present invention is not damaged.

The dicing die-bonding film according to the present embodiment can be manufactured as follows. In the following, the manufacturing method is explained using a dicing die-bonding film 10 as an example. First, the base 1 can be formed with a conventionally known film formation method. Examples of the film formation method include a calendar film formation method, a casting method in an organic solvent, an inflation extrusion method in a closed system, a T die extrusion method, a co-extrusion method, and a dry lamination method.

Next, the pressure-sensitive adhesive layer 2 is formed by applying the pressure-sensitive adhesive composition onto the base 1 and drying (by heat-crossing if necessary). Examples of the application method include roll coating, screen coating, and gravure coating. The coating may be performed directly onto the base 1, or the coating may be performed onto a peeling paper, etc. whose surface has undergone a peeling treatment.

On the other hand, a coating layer is formed by applying a forming material to form the die-bonding film 3 onto the peeling paper so as to become a prescribed thickness and then by drying under a prescribed condition. The die-bonding film 3 is formed by transferring this coating layer onto the pressure-sensitive adhesive layer 2. The die-bonding film 3 can also be formed by directly coating the forming material onto the pressure-sensitive adhesive layer 2 and then drying under a prescribed condition. Accordingly, the dicing die-bonding film 10 according to the present invention can be obtained.

(Method for Manufacturing Semiconductor Device)

Next, a method for manufacturing a semiconductor device using the die-bonding film according to the present embodiment is explained. FIG. 3 is a schematic sectional view showing an example of loading a semiconductor element with the die-bonding film.

The method for manufacturing a semiconductor device according to the present embodiment has a fixing step of fixing a semiconductor chip (semiconductor element) 5 onto the adherend 6 with a wafer pasting portion 3a of the die-bonding film 3 (referred to as a die-bonding film 3a below) interposed therebetween and a wire bonding step of wire bonding. It has a resin sealing step of sealing the semiconductor chip 5 with a sealing resin 8 and a post-curing step of after curing the sealing resin 8 as well.

Examples of the adherend 6 include such as a lead frame, a TAB film, a substrate, and a semiconductor chip separately produced. The adherend 6 may be a deformable adherend that are easily deformed, or may be a non-deformable adherend (a semiconductor wafer, etc.) that is difficult to deform, for example. A conventionally known substrate can be used as the substrate. Further, a metal lead frame such as a Cu lead frame and a 42 Alloy lead frame and an organic substrate composed of glass epoxy, BT (bismaleimide-triazine), and polyimide can be used as the lead frame. However, the present invention is not limited to this, and includes a circuit substrate that can be used by mounting a semiconductor element and electrically connecting with the semiconductor element.

The fixing step is a step of die bonding the semiconductor chip 5 to the adherend 6 with the die-bonding film 3a interposed therebetween as shown in FIG. 1. In this step, the die-bonding film 3a is heat-cured and the semiconductor chip 5 is completely adhered onto the adherend 6 by performing a heat treatment under a prescribed condition. The temperature when performing the heat treatment is preferably 100 to 200° C., and more preferably 120 to 180° C. The heat treatment time is preferably 0.25 to 10 hours, and more preferably 0.5 to 8 hours. An example of the method of fixing the semiconductor chip 5 onto the adherend 6 is a method of fixing by laminating the die-bonding film 3a onto the adherend 6 and then laminating the semiconductor chip 5 one by one on the die-bonding film 3a so that the wire bond surface becomes the upper side. The semiconductor chip 5 in which the die-bonding film 3a is fixed in advance may be fixed and laminated to the adherend 6.

The wire bonding step is a step of electrically connecting the tip of a terminal (inner lead) of the adherend 6 and an electrode pad (not shown) on the semiconductor chip 5 with a bonding wire 7. Examples of the bonding wire 7 include a gold wire, an aluminum wire, and a copper wire. The temperature when performing the wire bonding is 80 to 250° C., and preferably 80 to 220° C. The heating time is a few seconds to a few minutes. The wire connection is performed using vibrational energy due to ultrasonic waves and a bonding energy by applying pressure together while being heated to the temperature in the above-described range.

The resin sealing step is a step of sealing the semiconductor chip 5 with the sealing resin 8. The present step is performed to protect the semiconductor chip 5 that is loaded on the adherend 6 and the bonding wire 7. The present step is performed by molding the resin for sealing with a mold. An example of the sealing resin 8 is an epoxy resin. The heating temperature during the resin sealing is normally 175° C., and it is performed for 60 to 90 seconds. However, the present invention is not limited thereto, and the curing can be performed at 165 to 185° C. for a few minutes for example. Accordingly, the sealing resin is cured. In the present invention, voids between the die-bonding film 3a and the adherend 6 can be eliminated after the resin sealing step even when the heat treatment is performed to heat-cure the die-bonding film 3a in the die-bonding step.

In the post-curing step, the sealing resin 8 that is not sufficiently cured in the sealing step is completely cured. The heating temperature in the present step is in the range of 165 to 185° C., and the heating time is about 0.5 to 8 hours, for example, depending on the type of the sealing resin. In this step, a die-bonding film 3a can be thermally cured completely. In that case, the thermosetting catalyst is preferably compounded in the die-bonding film 3a. With this configuration, polymerization reaction occur between the remaining unreacted epoxy groups, and thermal curing of the die-bonding film 3a proceeds further. As a result, a semiconductor chip 5 can be securely fixed onto the adherend interposing the die-bonding film 3a therebetween.

The semiconductor package that is obtained in such a manner has a high reliability that can withstand, for example, even when a humidity resistance solder reflow test is performed. The humidity resistance solder reflow test is performed with a conventionally known method.

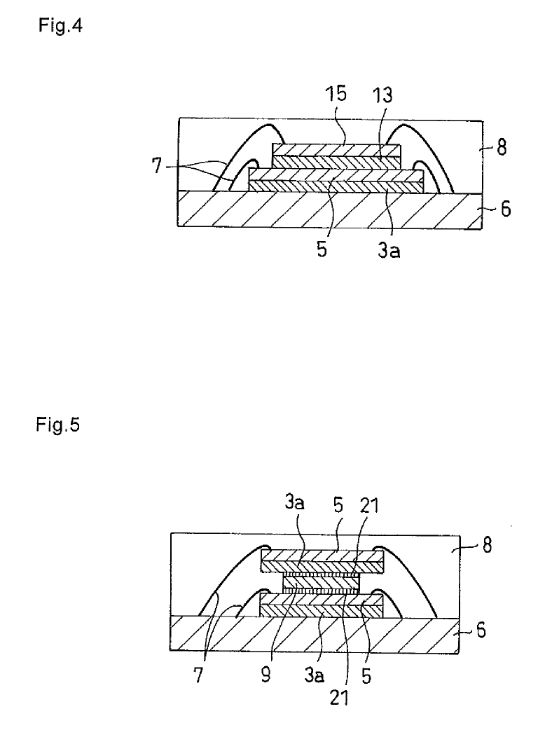

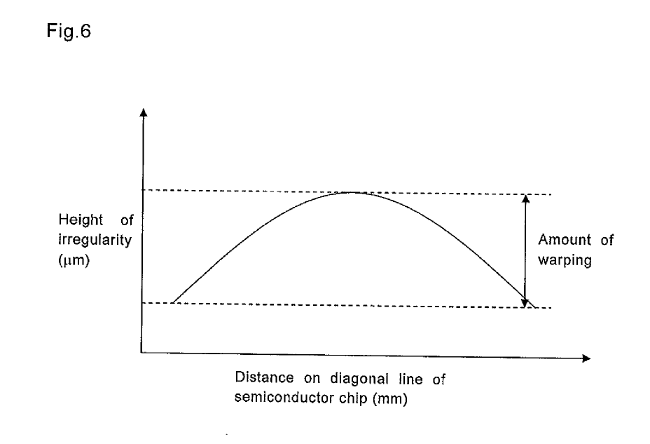

The dicing die-bonding film of the invention also can be preferably used in the case of three-dimensional mounting also in which plural semiconductor chips are laminated, as illustrated in FIG. 4. FIG. 4 is a schematic sectional view illustrating an example wherein semiconductor chips are three-dimensionally mounted through a die-bonding film. In the case of the three-dimensional mounting illustrated in FIG. 4, at least one die-bonding film 3a cut out so as to have a size equal to that of a semiconductor chip is bonded to the adherend 6, and then the semiconductor chip 15 is bonded onto the adherend 6 through the die-bonding film 3a so as to direct its wire bonding face upwards. Next, a die-bonding film 13 is bonded onto the semiconductor chip 5 avoiding its electrode pad portions. Furthermore, another semiconductor chip 15 is bonded onto the die-bonding film 13 so as to direct its wire bonding face upwards.

Next, a wire bonding step is performed. In this way, individual electrode pads on the semiconductor chip 5 and the other semiconductor chip 15 are electrically connected with the adherend 6 through bonding wires 7.

Subsequently, a sealing step of sealing the semiconductor chip 5 and on the like with a sealing resin 8 is performed to cure the sealing resin. In addition thereto, in the case of the temporary sticking/fixing, the adherend 6 and the semiconductor chip 5 are bonded to each other through the die-bonding film 3a. Also, the semiconductor chip 5 and the other semiconductor chip 15 are bonded to each other through the die-bonding film 13. After the sealing step, an after-curing step may be performed.

In the case of the three-dimensional mounting of the semiconductor chips, the production process is simplified and the yield is improved since heating treatment by heating the die-bonding films 3a and 13 is not conducted. Furthermore, the adherend 6 is not warped, and the semiconductor chips 5 and 15 are not cracked; thus, the semiconductor element can be made still thinner.

Three-dimensional mounting may performed in which semiconductor chips are laminated through die-bonding films so as to interpose a spacer between the semiconductor chips, as illustrated in FIG. 5. FIG. 5 is a schematic sectional view illustrating an example wherein two semiconductor chips are three-dimensionally mounted through die-bonding films so as to interpose a spacer between the chips.

In the case of the three-dimensional mounting illustrated in FIG. 5, first, a die-bonding film 3a, a semiconductor chip 5, and a die-bonding film 21 are successively laminated on a adherend 6 to bond these members. Furthermore, on the die-bonding film 21 are successively laminated a spacer 9, another die-bonding film 21, another die-bonding film 3a, and another semiconductor chip 5 to bond these members.

Next, as illustrated in FIG. 5, a wire bonding step is performed. In this way, electrode pads on the semiconductor chips 5 are electrically connected with the adherend 6 through bonding wires 7.

Subsequently, a sealing step of sealing the semiconductor chips 5 with a sealing resin 8 is performed to cure the sealing resin 8. In this way, a semiconductor package is obtained. The sealing step is preferably performed by a package sealing method wherein only the semiconductor chip 5 is sealed. The sealing is performed to protect the semiconductor chips 5 adhered onto the adhesive sheet (s). The method therefor is typically a method of using the sealing resin 8 and molding the resin 8 in a metal mold. At this time, it is general to use a metal mold composed of an upper metal mold part and a lower metal mold part and having plural cavities to seal simultaneously. The heating temperature at the time of the sealing preferably ranges, for example, from 170 to 180° C. After the sealing step, an after-curing step may be performed.

The spacer 9 is not particularly limited, and may be made of, for example, a silicone chip or polyimide film and the like known in the prior art. The spacer may be a core member. The core member is not particularly limited, and may be a core member known in the prior art. Specific examples thereof include films (such as a polyimide film, a polyester film, a polyethylene terephthalate film, a polyethylene naphthalate film, a polycarbonate film and the like), resin substrates each reinforced with glass fiber or plastic nonwoven fiber, mirror silicon wafers, silicon substrates, and glass substrates.

Next, the semiconductor package is surface-mounted on a printed wiring board. An example of a method of the surface mounting is reflow soldering in which solder is supplied onto the printed wiring board in advance and then heat-melted, and the soldering is performed. Examples of the heating method include hot air reflow and infrared ray reflow. It may be any method of entire heating or local heating. The heating temperature is preferably in the range of 240 to 265° C., and the heating time is preferably in the range of 1 to 20 seconds.

(Other Items)

When the semiconductor element is three-dimensionally mounted on the substrate, a buffer coat film is formed on the surface where a circuit of the semiconductor element is formed. Examples of the buffer coat film are a silicon nitride film and a film made of a heat resistant resin such as polyimide resin.

When the semiconductor element is three-dimensionally mounted, the die-bonding film used in each step is not limited to a die-bonding film made of the same composition, and it can be appropriately changed depending on manufacturing conditions, uses thereof, etc.

The above-described embodiment describes an aspect in which the wire bonding step is performed collectively after a plurality of semiconductor elements are laminated on the substrate, etc. However, the present invention is not limited thereto. For example, it is possible to perform the wire bonding step each time the semiconductor element is laminated onto the substrate, etc.

In the following, preferred examples of the present invention are explained in detail. However, the present invention is not limited to these examples unless there is a description that limits materials, the compounding amount, and the like in the examples below. Further, “part” means part by weight.

### Example 1

7.7 wt % of an acrylic acid ester-based polymer containing ethyl acrylate-methyl methacrylate as a main component (manufactured by Negami Chemical Industrial Co., Ltd., Paracron W-197CM), 18.6 wt % of an epoxy resin A (manufactured by Japan Epoxy Resins Co., Ltd., Epikote 1004), 12.0 wt % of an epoxy resin B (manufactured by Japan Epoxy Resins Co., Ltd., Epikote 827), 21.7 wt % of a phenol resin (manufactured by Mitsui Chemicals, Inc., MILEX XLC-4L), 39.9 wt % of spherical silica (manufactured by ADMATECHS CO., LTD., SO-25R), and 0.1 wt % of a thermosetting catalyst (manufactured by SHIKOKU CHEMICALS CORPORATION, C11-Z) (0.166 parts by weight to 100 parts by weight of an organic component excluding the spherical silica) were dissolved in methyl ethyl ketone to obtain an adhesive composition having a concentration of 23.6% by weight (however, methyl ethyl ketone was excluded from the organic component). The value of (the number of moles of epoxy groups in the thermosetting component of the adhesive composition)/(the number of phenolic hydroxyl groups in the thermosetting component of the adhesive composition) equalled 1.5.

This adhesive composition solution was applied on a release-treated film (peel liner) composed of a 50 μm thick polyethylene terephthalate film subjected to a silicone release treatment and then dried at 130° C. for 2 minutes to produce a 25 μm thick thermosetting die-bonding film.

### Example 2

7.7 wt % of an acrylic acid ester-based polymer containing ethyl acrylate-methyl methacrylate as a main component (manufactured by Negami Chemical Industrial Co., Ltd., Paracron W-197CM), 24.0 wt % of an epoxy resin A (manufactured by Japan Epoxy Resins Co., Ltd., Epikote 1004), 12.0 wt % of an epoxy resin B (manufactured by Japan Epoxy Resins Co., Ltd., Epikote 827), 16.3 wt % of a phenol resin (manufactured by Mitsui Chemicals, Inc., MILEX XLC-4L), 39.9 wt % of spherical silica (manufactured by ADMATECHS CO., LTD., SO-25R), and 0.1 wt % of a thermosetting catalyst (manufactured by SHIKOKU CHEMICALS CORPORATION, C11-Z) (0.166 parts by weight to 100 parts by weight of an organic component excluding the spherical silica) were dissolved in methyl ethyl ketone to obtain an adhesive composition having a concentration of 23.6% by weight (however, methyl ethyl ketone was excluded from the organic component). The value of (the number of moles of epoxy groups in the thermosetting component of the adhesive composition)/(the number of phenolic hydroxyl groups in the thermosetting component of the adhesive composition) equalled 2.3.

This adhesive composition solution was applied on a release-treated film (peel liner) composed of a 50 μm thick polyethylene terephthalate film subjected to a silicone release treatment and then dried at 130° C. for 2 minutes to produce a 25 μm thick thermosetting die-bonding film.

### Example 3

7.7 wt % of an acrylic acid ester-based polymer containing ethyl acrylate-methyl methacrylate as a main component (manufactured by Negami Chemical Industrial Co., Ltd., Paracron W-197CM), 29.4 wt % of an epoxy resin A (manufactured by Japan. Epoxy Resins Co., Ltd., Epikote 1004), 12.0 wt % of an epoxy resin B (manufactured by Japan Epoxy Resins Co., Ltd., Epikote 827), 10.9 wt % of a phenol resin (manufactured by Mitsui Chemicals, Inc., MILEX XLC-4L), 39.9 wt % of spherical silica (manufactured by ADMATECHS CO., LTD., SO-25R), and 0.1 wt % of a thermosetting catalyst (manufactured by SHIKOKU CHEMICALS CORPORATION, C11-Z) (0.166 parts by weight to 100 parts by weight of an organic component excluding the spherical silica) were dissolved in methyl ethyl ketone to obtain an adhesive composition having a concentration of 23.6% by weight (however, methyl ethyl ketone was excluded from the organic component). The value of (the number of moles of epoxy groups in the thermosetting component of the adhesive composition)/(the number of phenolic hydroxyl groups in the thermosetting component of the adhesive composition) equalled 4.

This adhesive composition solution was applied on a release-treated film (peel liner) composed of a 50 μm thick polyethylene terephthalate film subjected to a silicone release treatment and then dried at 130° C. for 2 minutes to produce a 25 μm thick thermosetting die-bonding film.

### Comparative Example 1

7.7 wt % of an acrylic acid ester-based polymer containing ethyl acrylate-methyl methacrylate as a main component (manufactured by Negami Chemical Industrial Co., Ltd., Paracron W-197CM), 13.3 wt % of an epoxy resin A (manufactured by Japan Epoxy Resins Co., Ltd., Epikote 1004), 12.0 wt % of an epoxy resin B (manufactured by Japan Epoxy Resins Co., Ltd., Epikote 827), 27 wt % of a phenol resin (manufactured by Mitsui Chemicals, Inc., MILEX XLC-4L), 39.9 wt % of spherical silica (manufactured by ADMATECHS CO., LTD., SO-25R), and 0.1 wt % of a thermosetting catalyst (manufactured by SHIKOKU CHEMICALS CORPORATION, C11-Z) (0.166 parts by weight to 100 parts by weight of an organic component excluding the spherical silica) were dissolved in methyl ethyl ketone to obtain an adhesive composition having a concentration of 23.6% by weight (however, methyl ethyl ketone was excluded from the organic component). The value of (the number of moles of epoxy groups in the thermosetting component of the adhesive composition)/(the number of phenolic hydroxyl groups in the thermosetting, component of the adhesive composition) equalled 1.

This adhesive composition solution was applied on a release-treated film (peel liner) composed of a 50 μm thick polyethylene terephthalate film subjected to a silicone release treatment and then dried at 130° C. for 2 minutes to produce a 25 μm thick thermosetting die-bonding film.

### Comparative Example 2

7.7 wt % of an acrylic acid ester-based polymer containing ethyl acrylate-methyl methacrylate as a main component (manufactured by Negami Chemical Industrial Co., Ltd., Paracron W-197CM), 34.8 wt % of an epoxy resin A (manufactured by Japan Epoxy Resins Co., Ltd., Epikote 1004), 12.0 wt % of an epoxy resin B (manufactured by Japan Epoxy Resins Co., Ltd., Epikote 827), 5.5 wt % of a phenol resin (manufactured by Mitsui Chemicals, Inc., MILEX XLC-4L), 39.9 wt % of spherical silica (manufactured by ADMATECHS CO., LTD., SO-25R), and 0.1 wt % of a thermosetting catalyst (manufactured by SHIKOKU CHEMICALS CORPORATION, C11-Z) (0.166 parts by weight to 100 parts by weight of an organic component excluding the spherical silica) were dissolved in methyl ethyl ketone to obtain an adhesive composition having a concentration of 23.6% by weight (however, methyl ethyl ketone was excluded from the organic component). The value of (the number of moles of epoxy groups in the thermosetting component of the adhesive composition)/(the number of phenolic hydroxyl groups in the thermosetting component of the adhesive composition) equalled 9.

This adhesive composition solution was applied on a release-treated film (peel liner) composed of a 50 μm thick polyethylene terephthalate film subjected to a silicone release treatment and then dried at 130° C. for 2 minutes to produce a 25 μm thick thermosetting die-bonding film.

### (Measurement of Melt Viscosity)

The melt viscosity at 120° C. was measured on each of the thermosetting die-bonding films that were produced in the examples and the comparative examples. That is, the melt viscosity was measured by a parallel plate method using a rheometer (manufactured by HAAKE, RS-1). From each of the thermosetting die-bonding films that were produced in the examples and the comparative examples, 0.1 g of a sample was prepared and placed on a plate heated to 100° C. in advance. Next, The melt viscosity was defined as a value measured after 120 seconds from the start of the measurement. The gap between the plates was 0.1 mm. The results are shown in Table 1.

### (Reflow Resistance)

Each of the thermosetting die-bonding films that were produced in the examples and the comparative examples was attached onto a 10 mm square and 50 μm thick semiconductor chip at a temperature of 40° C. Then, the semiconductor chip was pre-fixed to a BGA substrate through the thermosetting die-bonding film. The conditions at that time were as follows: a temperature of 120° C., a pressure of 0.2 MPa, and a period of 2 seconds. The thermosetting die-bonding film was thermally cured by performing a heat treatment on the BGA substrate on which the semiconductor chip was fixed in a dryer at 120° C. for 1 hour.

Next, packaging of the semiconductor chip was performed with a sealing resin (manufactured by Nitto Denko Corporation, GE-100) (a resin sealing step). After that, the sealing resin was thermally cured at a temperature of 175° C. for 5 hours (a post curing step).

Further, moisture absorption was performed at 85° C. and 60% Rh for 168 hours, and the semiconductor package was placed on a conveyor type reflow apparatus (manufactured by TAMURA CORPORATION, TAP30-407PM) at 260° C. for 10 seconds. Then, presence or absence of cracks in the semiconductor package was confirmed by observing the semiconductor package with an ultrasonic image apparatus (manufactured by Hitachi Construction Machinery Co., Ltd., FineSAT II). The case when no crack was generated is marked as ◯, and the case when cracks were generated is marked as x. The results are shown in Table 1.

### (Storage Modulus at 260° C.)

A heat treatment at 140° C. for 2 hours was performed on each of the thermosetting die-bonding films that were produced in the examples and the comparative examples, and then the film was thermally cured by performing a heat treatment at 175° C. for 1 hour. Then, each of the thermosetting die-bonding films after thermal curing was cut into a rectangular shape of 200 μm thick, 400 mm long, and 10 mm wide with a cutting knife. The tensile storage modulus and the loss modulus of these samples at −50 to 300° C. were measured using a solid viscoelasticity measurement apparatus (RSA-III manufactured by Rheometric Scientific, Inc.) under conditions of a frequency of 1 Hz and a temperature rising speed of 10° C./min. The storage modulus (E′) was obtained by reading a value at 260° C. in this measurement. The results are shown in Table 1.

### (Measurement of Glass Transition Temperature (Tg))

Each of the thermosetting die-bonding films that were produced in the examples and the comparative examples was thermally cured by performing a heat treatment at 140° C. for 2 hours. Then, each of the thermosetting die-bonding films after thermal curing was cut into a rectangular shape of 200 μm thick, 400 mm long, and 10 mm wide with a cutting knife. The tensile storage modulus and the loss modulus of these samples at −50 to 300° C. were measured using a solid viscoelasticity measurement apparatus (RSA-III manufactured by Rheometric Scientific, Inc.) under conditions of a frequency of 1 Hz and a temperature rising speed of 10° C./min. The glass transition temperature was obtained by reading the peak value of tan (δ) in this measurement. The results are shown in Table 1.

### (Amount of Warping)

Each of the thermosetting die-bonding films that were produced in the examples and the comparative examples was attached onto a 10 mm square and 50 μm thick semiconductor chip at a temperature of 40° C. Then, the semiconductor chip was mounted onto a resin substrate with a solder resist (a glass epoxy substrate, 0.23 mm in thickness) through each of the thermosetting die-bonding films. The conditions at that time were as follows: a temperature of 120° C., a pressure of 0.2 MPa, and a period of 2 seconds. Each thermosetting die-bonding film was thermally cured by performing a heat treatment on the resin substrate on which the semiconductor chip was mounted in a dryer at 140° C. for 2 hours.

Next, the sample was loaded onto a flat plate so that the resin substrate became positioned on the lower side, and irregularity on a diagonal line of the semiconductor chip was measured. With this operation, the height of the semiconductor chip that was separating from the flat plate, that is, the amount of warping (μm), was measured. In the measurement, both ends on the diagonal line of the semiconductor chip were corrected to be equalized (to be 0). The measurement was performed under conditions of a measurement speed of 1.5 mm/s and a load of 1 g using a surface roughness meter (manufactured by Veeco Instruments, DEKTAK 8). As a result of the measurement, the case when the amount of warping was 50 μm or less is marked as ◯, and the case when it exceeded 50 μm is marked as x. The results are shown in Table 1.

### RESULT

As seen in the results of Examples 1 to 3 in Table 1, when the ratios of the number of moles of epoxy groups in the thermosetting component to the number of moles of phenolic hydroxyl groups in the thermosetting component were 1.5, 2.3 and 4, the amount of warping of each resin substrate with a solder resist was 50 μm or less and it was confirmed that curing contraction of the thermosetting die-bonding film was suppressed. Further, it was revealed that package cracks did not occur and the reflow resistance was excellent. On the other hand, when the ratio of the number of moles of epoxy groups to the number of moles of phenolic hydroxyl groups was 1 as in Comparative Example 1, the amount of warping became 96 μm due to curing contraction of the thermosetting die-bonding film. On the other hand, when the ratio of the number of moles of epoxy groups to the number of moles of phenolic hydroxyl groups was 9 as in Comparative Example 2, the amount of warping was 0 μm. However, it was revealed that package cracks occurred and the reflow resistance was deteriorated.

| | | | | | Com- |
|---|---|---|---|---|---|
| | | | | Com- | parative |
| | | | | parative | Ex- |
| | Example 1 | Example 2 | Example 3 | Example 1 | ample 2 |
| Number of | 1.5 | 2.3 | 4 | 1 | 9 |
| moles of epoxy | | | | | |
| groups/number | | | | | |
| of moles of | | | | | |
| phenolic | | | | | |
| hydroxyl | | | | | |
| groups | | | | | |
| Thermosetting | 0.166 | 0.166 | 0.166 | 0.166 | 0.166 |
| catalyst | | | | | |
| (parts by | | | | | |
| weight) | | | | | |
| Glass | 75 | 60 | 48 | 112 | 45 |
| transition | | | | | |
| temperature | | | | | |
| (° C.) | | | | | |
| Amount of | 34 | 13 | 2 | 96 | 0 |
| warping (μm) | | | | | |
| Melt | 342 | 364 | 398 | 362 | 338 |
| viscosity | | | | | |
| (Pa · s) | | | | | |
| Storage | 1 or more | 1 or more | 1 or more | 1 or more | 1 or less |
| modulus (MPa) | | | | | |
| Reflow | ◯ | ◯ | ◯ | ◯ | X |
| resistance | | | | | |

1. A thermosetting die-bonding film for adhering and fixing a semiconductor element onto an adherend, comprising at least an epoxy resin and a phenol resin as a thermosetting component, wherein
the ratio of the number of moles of epoxy groups in the thermosetting component to the number of moles of phenolic hydroxyl groups in the thermosetting component is in a range of 1.5 to 6.

2. The thermosetting die-bonding film according to claim 1, wherein a thermosetting catalyst is compounded in an amount of 0.07 to 3.5 parts by weight to 100 parts by weight of an organic component.

3. The thermosetting die-bonding film according to claim 1, wherein the glass transition temperature after thermal curing at 140° C. for 2 hours is 80° C. or less.

4. The thermosetting die-bonding film according to claim 1, wherein the melt viscosity at 120° C. before thermal curing is in a range of 50 to 1000 Pa·s.

5. The thermosetting die-bonding film according to claim 1, wherein the storage modulus at 260° C. after complete thermal curing is 1 MPa or more.

6. A dicing die-bonding film having a structure in which the thermosetting die-bonding film according to claim 1 is laminated on a dicing film.

7. A semiconductor device manufactured by using the dicing die-bonding film according to claim 6.

8. The thermosetting die-bonding film according to claim 1, wherein the thermosetting die-bonding film further comprises a thermoplastic component.

9. The thermosetting die-bonding film according to claim 8, wherein, in the thermosetting die-bonding film, a combined amount of the epoxy resin and the phenol resin is 10 to 700 parts by weight relative to 100 parts by weight of the thermoplastic component.

10. The thermosetting die-bonding film according to claim 2, wherein the thermosetting catalyst is insoluble in the epoxy resin.

11. The dicing die-bonding film according to claim 6, wherein the dicing die-bonding film comprises a pressure-sensitive adhesive layer laminated on a base, and the die-bonding film is laminated on the pressure-sensitive adhesive layer.

12. A thermosetting die-bonding film for adhering and fixing a semiconductor element onto an adherend, comprising an uncured die-bonding layer, wherein the uncured die-bonding layer comprises at least an epoxy resin and a phenol resin as a thermosetting component, wherein the ratio of the number of moles of epoxy groups in the thermosetting component to the number of moles of phenolic hydroxyl groups in the thermosetting component is in a range of 1.5 to 6.
